(19) United States
(12) Patent Application Publication
(10) Pub. No.: US 2014/0038394 A1
(43) Pub. Date: Feb. 6, 2014

(54) METHOD AND APPARATUS OF FORMING COMPOUND SEMICONDUCTOR FILM

(71) Applicant: TOKYO ELECTRON LIMITED, Tokyo (JP)

(72) Inventors: Yosuke WATANABE, Nirasaki City (JP); Kota UMEZAWA, Niraski City (JP)

(73) Assignee: TOKYO ELECTRON LIMITED, Tokyo (JP)

(21) Appl. No.: 13/958,195

(22) Filed: Aug. 2, 2013

(30) Foreign Application Priority Data
Aug. 3, 2012 (JP) 2012-173334
Aug. 6, 2012 (JP) 2012-174055

(51) Int. Cl. H01L 21/02

(52) U.S. Cl. CPC H01L 21/0254
USPC 438/478; 118/725

(57) ABSTRACT

A method for forming a compound semiconductor film on a substrate to be processed, which includes: mounting a plurality of substrates to be processed on a substrate mounting jig; loading the substrates to be processed into a processing chamber; and heating the substrates to be processed loaded into the processing chamber; supplying a gas containing one element that constitutes a compound semiconductor, and another gas containing another element that constitutes the compound semiconductor and being different from the one element, into the processing chamber in which the substrates to be processed are loaded; and forming the compound semiconductor film on each of the substrates to be processed.

### CROSS-REFERENCE TO RELATED APPLICATION

This application claims the benefit of Japanese Patent Application No. 2012-173334, filed on Aug. 3, 2012, and Japanese Patent Application No. 2012-174055, filed on Aug. 6, 2012, in the Japan Patent Office, the disclosures of which are incorporated herein in its entirety by reference.

### TECHNICAL FIELD

The present disclosure relates to a method and apparatus of forming a compound semiconductor film.

### BACKGROUND

Among compound semiconductors, a semiconductor using nitrogen (N) as a chemical element of a V group is called a nitride semiconductor. Typical examples of the nitride semiconductor include aluminum nitride (AlN), gallium nitride (GaN) and indium nitride (InN) and the like.

From among these, gallium nitride is in use as a blue light-emitting element in the optical application field. Further, in an electronic device application field, the gallium nitride is utilized as a high electron mobility transistor (HEMT), which is used in a communication field.

In addition, the gallium nitride, which is a wide-gap semiconductor, has a property that is antagonistic to silicon carbide (SiC). The gallium nitride is known to have relatively high potential in a high-frequency environment and a dielectric breakdown withstanding voltage as compared with the silicon carbide. Recently, intensive research is under way to realize further practical uses of gallium nitride, that is, to develop a novel device which is capable of covering a wide range of properties such as a high frequency, a high speed and a high power.

Known typical methods of forming a gallium nitride film include hydride vapor phase epitaxy (HVPE) and a sodium (Na) flux.

Hydrogen chloride gas (HCl), in a typical HVPE method, reacts with a gallium (Ga) metal under a high temperature environment to create a gallium trichloride gas (GaCl₃), and subsequently, the formed gallium trichloride gas reacts with an ammonia gas (NH₃) to vapor-deposit a gallium nitride crystal on a sapphire substrate.

The typical HVPE method is sometimes referred to as a “halide vapor phase epitaxy.”

The typical Na flux method dissolves nitrogen in a mixed solution of gallium and sodium (Na) to liquid-deposite a gallium nitride crystal on the sapphire substrate.

Although the HVPE method is capable of forming a relatively thick compound semiconductor film on the sapphire substrate, it requires higher costs for film forming per substrate as compared with, for example, the Na flux method.

On the other hand, although the Na flux method is capable of forming the film with relatively low costs as compared with the HVPE method, it results in a low production yield.

In view of the foregoing, there is known a conventional method which simultaneously vapor-deposits compound semiconductor films on a plurality of sapphire substrates in the typical HVPE method, thus enhancing the production yield and reducing the film forming cost per substrate. In addition, the conventional method supplies a reaction product gas (GaCl₃) containing a chemical element (gallium) from III group and a hydride gas (NH₃) containing a chemical element from V group into a reaction unit through a plurality of divided nozzles such that the compound semiconductor films are uniformly and efficiently formed on the sapphire substrates.

However, the conventional method is outdated in terms of the surface morphology of the compound semiconductor film to be formed and in-plane uniformity in the film thickness of the compound semiconductor film.

### SUMMARY

Some embodiments of the present disclosure provide a compound semiconductor film forming method and apparatus thereof, which are capable of improving a production yield, reducing film forming costs, enhancing in-plane uniformity in film thickness of the compound semiconductor film to be formed and achieving an improved surface morphology.

According to one embodiment of the present disclosure, provided is a method for forming a compound semiconductor film on a substrate to be processed, which includes: mounting a plurality of substrates on a substrate mounting jig; loading the substrates to be processed into a processing chamber; and heating the substrates to be processed loaded into the processing chamber; supplying a gas containing one element that constitutes a compound semiconductor, and another gas containing another element that constitutes the compound semiconductor and being different from the one element, into the processing chamber in which the substrates to be processed are loaded; and forming the compound semiconductor film on each of the substrates to be processed. The loading includes: mounting the substrates to be processed on the substrate mounting jig while leaving at least one blank therebetween; placing a ring for film forming adjustment which is used in forming the compound semiconductor film on the substrate to be processed in the at least one bank; and loading the substrates to be processed and the rings for film forming adjustment into the processing chamber. The forming includes forming the compound semiconductor films on the substrates to be processed while a film forming surface of each of the substrates to be processed being disposed to face each of the rings for film forming adjustment.

According to another embodiment of the present disclosure, provided is a An apparatus of forming a compound semiconductor film on a substrate to be processed, which includes: a processing chamber configured to accommodate a substrate mounting jig on which a plurality of substrates to be processed are mounted, the compound semiconductor film being formed on each of the plurality of substrates to be processed; a gas supply unit configured to supply a gas containing one element that constitutes a compound semiconductor and another gas containing another element that constitutes the compound semiconductor and being different from the one element into the processing chamber accommodating the substrates to be processed therein; a heating unit configured to heat the substrates to be processed accommodated in the processing chamber; a mounting and loading unit configured to mount the substrates to be processed on the substrate mounting jig and configured to load the substrates to be processed mounted on the substrate mounting jig into the processing chamber; and a control unit configured to control the gas supply unit, the heating unit and the mounting and loading unit. The control unit is configured to control the gas supply unit, the heating unit and the mounting and loading unit to perform the method of claim 1.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a cross sectional view schematically showing an example of a batch-type vertical film forming apparatus which is capable of performing a compound semiconductor film forming method according to an embodiment of the present disclosure.

FIG. 2A is a sectional view showing a state where substrates to be processed and rings for film forming adjustment are mounted on a substrate mounting jig.

FIG. 2B is a plane view of FIG. 2A.

FIG. 3 is a flowchart illustrating an example of a compound semiconductor film forming method according to a first embodiment of the present disclosure.

FIG. 4A is a sectional view showing a state where substrates to be processed are mounted on a substrate mounting jig according to a first reference example.

FIG. 4B is a sectional view showing a state where substrates to be processed are mounted on a substrate mounting jig according to a second reference example.

FIG. 5 is a view showing the relationship between a Y-axis position of a substrate to be processed and a deposition rate.

FIG. 6 is a photograph showing a surface morphology of a gallium nitride film which is formed by a compound semiconductor film forming method according to the first reference example.

FIG. 7 is a photograph showing a surface morphology of a gallium nitride film which is formed by the compound semiconductor film forming method according to the first embodiment.

FIGS. 8A and 8B are views showing the relationship between a gallium concentration and a substrate position.

FIG. 9 is a sectional view showing a state where substrates to be processed are mounted on a substrate mounting jig according to a premise example of a second embodiment.

FIG. 10 is a sectional view showing a state where substrates to be processed are mounted on a substrate mounting jig using a compound semiconductor film forming method according to the second embodiment of the present disclosure.

FIG. 11 is a sectional view showing a state where substrates to be processed and substrate for film forming adjustment are mounted on a substrate mounting jig according to a first modified example of the second embodiment.

FIG. 12 is a sectional view showing a state where substrates to be processed and substrates for film forming adjustment are mounted on a substrate mounting jig according to a second modified example of the second embodiment.

FIG. 13 is a sectional view showing a state where substrates to be processed and substrates for film forming adjustment are mounted on a substrate mounting jig according to a third modified example of the second embodiment.

FIG. 14 is a sectional view showing a state where substrates to be processed and substrates for film forming adjustment are mounted on a substrate mounting jig according to a fourth modified example of the second embodiment.

FIG. 15 is a sectional view showing a state where substrates to be processed and substrates for film forming adjustment are mounted on a substrate mounting jig according to a third embodiment of the present disclosure.

FIG. 16 is a flowchart illustrating an example of a compound semiconductor film forming method according to the third embodiment of the present disclosure.

FIG. 17 is a sectional view showing a state where substrates to be processed and substrates for film forming adjustment are mounted on a substrate mounting jig according to a modified example of the third embodiment of the present disclosure.

FIG. 18 is a sectional view showing a state where substrates to be processed are mounted on a substrate mounting jig using a compound semiconductor film forming method according to a fourth embodiment of the present disclosure.

FIG. 19 is a sectional view showing a state where substrates to be processed are mounted on a substrate mounting jig according to a modified example of the fourth embodiment of the present disclosure.

FIG. 20 is a vertical sectional view schematically showing an example of a batch-type film forming apparatus according to a firth embodiment of the present disclosure.

FIG. 21 is a horizontal sectional view schematically showing an example of the batch-type film forming apparatus according to the fifth embodiment of the present disclosure.

FIG. 22 is a block diagram showing a configuration of a chloride gas generating unit.

FIG. 23 is a sectional view showing a modified example of a substrate mounting jig.

### DETAILED DESCRIPTION

Embodiments will now be described in detail with reference to the drawings. In the following description and the drawings, like reference numerals refer to the same or similar configurations and functions and explanation thereof will not be repeated.

### First Embodiment

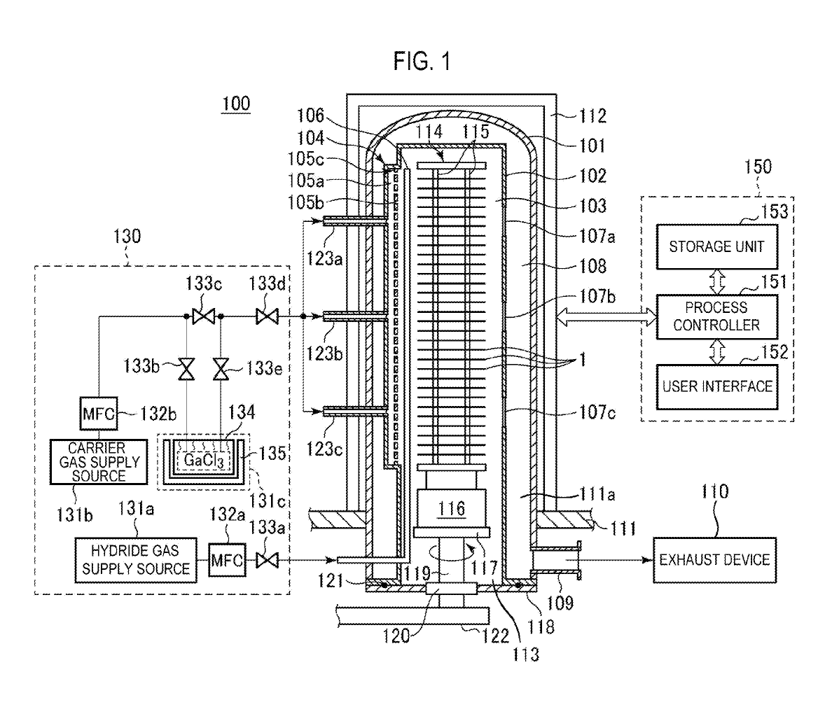

FIG. 1 is a sectional view schematically showing an example of a batch-type vertical film forming apparatus which is capable of performing a compound semiconductor film forming method according to a first embodiment of the present disclosure.

As shown in FIG. 1, a batch-type vertical film forming apparatus (hereinafter, referred to as a “film forming apparatus”) 100 includes a cylindrical outer tube 101 having a ceiling, and a cylindrical inner tube 102 having a ceiling and installed inside the outer tube 101. The outer tube 101 and the inner tube 102 may be made of, e.g., quartz. The inside of the inner tube 102 is referred to as a processing chamber 103 in which a plurality of substrates to be processed (in this embodiment, a plurality of sapphire substrates 1) are accommodated. Compound semiconductor films (e.g., compound semiconductor films from III-V group) are formed on the plurality of sapphire substrates 1 accommodated in the processing chamber 103 in batches. In this embodiment, the compound semiconductor films from III-V group (e.g., nitride semiconductor films using nitrogen (N) as a chemical element from V group) are formed. Examples of the nitride semiconductor film may include a gallium nitride film.

A gas introduction portion 104 configured to introduce a process gas into the processing chamber 103 is installed at one side of sidewalls of the inner tube 102. The gas introduction portion 104 includes a gas diffusion space 105a in which a diffusion plate 105c is disposed. The diffusion plate 105c is provided with a plurality of gas discharge holes 105b formed along a vertical direction, through which the process gas is supplied into the processing chamber 103.

A gas introduction pipe 106 is installed inside the inner tube 102 to introduce another process gas, which is different from the process gas discharged through the gas discharge holes 105b, into the processing chamber 103. Similarly, in the gas introduction pipe 106, a plurality of gas discharge holes (not shown), through which another process gas is supplied into the processing chamber 103, are formed along the height direction.

At the other side of the sidewalls of the inner tube 102, a plurality of exhaust ports 107a, 107b and 107c are formed to exhaust gas from the processing chamber 103. These exhaust ports 107a, 107b and 107c are formed corresponding to each zone defined inside the processing chamber 103. In this embodiment, the exhaust port 107a is formed in an upper zone, the exhaust port 107b is formed in a middle zone, and the exhaust port 107c is formed in a lower zone. The exhaust ports 107a, 107b and 107c are connected to each other through a space defined by the outer tube 101 and the inner tube 102. The space serves as an exhaust space 108, which is connected through an exhaust pipe 109 to an exhaust device 110 configured to exhaust the processing chamber 103. The exhaust device 110 has a function of adjusting an internal pressure of the processing chamber 103 to a pressure required for processing, in addition to exhausting an internal atmospheric of the processing chamber.

The outer tube 101 and the inner tube 102 are inserted through an opening portion 111a of a base member 111. A heating device 112 is installed on the base member 111 to surround the outer tube 101. The heating device 112 heats the plurality of sapphire substrates 1 accommodated in the processing chamber 103.

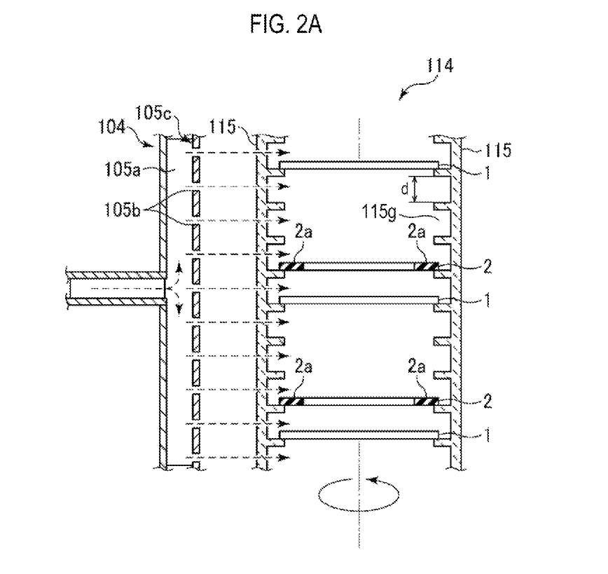

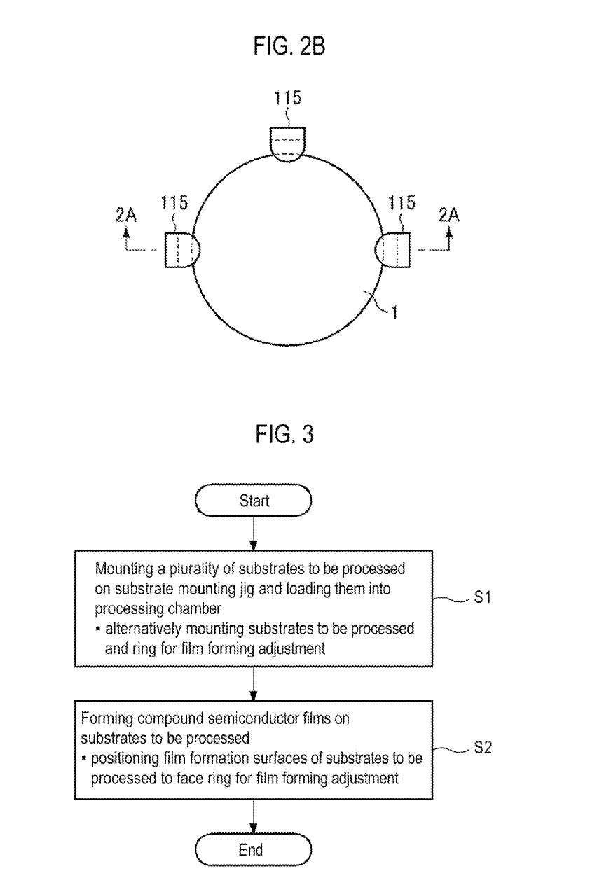

A lower portion of the processing chamber 103 is opened to form an opening 113. Through the opening 113, a boat 114 used as a substrate mounting jig is loaded into and unloaded from the processing chamber 103. The boat 114 may be made of, e.g., quartz, and is provided with a plurality of quartz posts 115. As shown in FIG. 2A, grooves 115g having a height of d are formed in each of the posts 115. The plurality of sapphire substrates 1 are collectively supported by the grooves 115g. With this configuration, the boat 114 can vertically support the plurality of (e.g., 50 to 150) sapphire substrates 1 as substrates to be processed. The boat 114 supporting the plurality of sapphire substrates 1 is loaded into the processing chamber 103 so that the plurality of sapphire substrates 1 are accommodated in the processing chamber 103.

The boat 114 is mounted on a table 117 through a heat insulating tube 116 of quartz. The table 117 is supported by a rotation shaft 119 that passes through a lid 118 made of, e.g., a stainless steel. During a film forming, the boat 114 is rotated with the rotation of the rotation shaft 119. While the boat 114 is being rotated, for example, the gallium nitride films are formed on the plurality of sapphire substrates 1 mounted on the boat 114.

The lid 118 is configured to open and close the opening 113. For example, a magnetic fluid seal 120 is installed at a through portion of the lid 118 to air-tightly seal the rotation shaft 119 and rotatably support the rotation shaft 119. A seal member 121 formed of, e.g., an O-ring, is disposed between a peripheral portion of the lid 118 and a bottom end portion of the inner tube 102, thus maintaining sealability in the processing chamber 103. The rotation shaft 119 is installed at a front end of an arm 122 that is supported by an elevating mechanism (not shown) such as a boat elevator. With this configuration, the boat 114 and the lid 118 are integrally elevated so that they are loaded into and unloaded from the processing chamber 103.

The film forming apparatus 100 includes a process gas supply mechanism 130 configured to supply a process gas into the processing chamber 103. In this embodiment, the process gas supply mechanism 130 is provided with a hydride gas supply source 131a, a carrier gas supply source 131b and a chloride gas supply source 131c.

The hydride gas supply source 131a is connected to the gas introduction pipe 106 through a mass flow controller (MFC) 132a and an on-off valve 133a. The hydride gas supply source 131a of this embodiment supplies an ammonia (NH₃) gas as a hydride gas into the processing chamber 103 through the gas introduction pipe 106. Examples of the ammonia gas may include nitrogen (N) as a chemical element from V group.

The carrier gas supply source 131b is connected to one end of an on-off valve 133b and one end of a bypass on-off valve 133c through a mass flow controller (MFC) 132b. An inert gas is used as an example of a carrier gas. Examples of the inert gas may include a nitrogen (N₂) gas. The other end of the on-off valve 133b is connected to the chloride gas supply source 131c. The other end of the bypass on-off valve 133c is connected to one end of an on-off valve 133d. The other end of the on-off valve 133d is connected to gas introduction pipes 123a, 123b and 123c. The nitrogen gas can serve as the carrier gas for picking up and carrying a chloride gas, and also can serve as a purge gas for purging the inside of the processing chamber 103 by closing the on-off valve 133b and opening the bypass on-off valve 133c.

The chloride gas supply source 131c includes a thermostat bath 134 and a heater 135 to heat the thermostat bath 134. The thermostat bath 134 accommodates a solid chloride therein. In this embodiment, a solid gallium trichloride (GaCl₃) as the solid chloride is accommodated in the thermostat bath 134. The thermostat bath 134 is connected to the other end of the on-off valve 133b and is connected to the one end of the on-off valve 133d through an on-off valve 133e.

When the solid chloride (e.g., the solid gallium trichloride) accommodated in the thermostat bath 134 is heated to a temperature of about 85 degrees C. by the heater 135, the solid gallium trichloride is dissolved to generate a gallium trichloride gas. The gallium trichloride gas is introduced together with the carrier gas into the gas introduction portion 104 through the on-off valves 133e and 133d by opening the on-off valve 133b and introducing the carrier gas (the nitrogen gas in this embodiment) into the thermostat bath 134 via the on-off valve 133b. In this embodiment, the gas introduction pipes 123a, 123b and 123c are disposed corresponding to the respective zones of the processing chamber 103 in the gas introduction portion 104. The on-off valve 133d is connected to each of the gas introduction pipes 123a, 123b and 123c. The gallium trichloride gas is supplied into the processing chamber 103 through the gas introduction portion 104.

As described above, a gas containing one element that constitutes a compound semiconductor film to be formed is supplied onto the film forming surfaces of the sapphire substrates 1 through the gas introduction portion 104. Further, a gas containing another element that constitutes the compound semiconductor film to be formed and being different from the one element, is supplied onto the film forming surfaces of the sapphire substrates 1 through the gas introduction pipe 106. In this embodiment, the one element is gallium (Ga) as a chemical element from III group, and the another element is nitrogen (N) as a chemical element from V group. The compound semiconductor film to be formed is a compound of elements from III-V group and may be a gallium nitride (GaN) film as one kind of nitride semiconductors.

A control unit 150 is connected to the film forming apparatus 100. The control unit 150 includes a process controller 151 provided with a microprocessor (computer), for example. Respective components of the film forming apparatus 100 are controlled by the process controller 151. A user interface 152 and a storage unit 153 are connected to the process controller 151.

The user interface 152 includes an input unit (not shown) such as a touch panel display or a keyboard for inputting, by an operator, a command to control the film forming apparatus 100, and a display unit (not shown) such as a display for displaying an operation state of the film forming apparatus 100.

A storage unit 153 stores a control program for executing various processes in the film forming apparatus 100 under the control of the process controller 151, and a program (i.e., process recipe) for executing a process in each component of the film forming apparatus 100 according to the process conditions. For example, the process recipe is stored in a memory medium of the storage unit 153. The memory medium may include a hard disk, a semiconductor memory, a CD-ROM, a DVD, and a portable memory such as a flash memory. The process recipe may be suitably transmitted from another device through a dedicated line.

If necessary, the process recipe is read from the storage unit 153 in response to the command received from the user interface 152, and the process controller 151 executes a process corresponding to the read process recipe. Thus, the film forming apparatus 100 performs a desired process under the control of the process controller 151.

In this embodiment, the control unit 150 further controls a mounting accommodation device (not shown). The mounting accommodation device mounts the sapphire substrates 1 on the substrate mounting jig (i.e., the boat 114) and conveys the sapphire substrates 1 mounted on the substrate mounting jig (i.e., the boat 114) into the processing chamber 103 to accommodate the same therein. In the compound semiconductor film forming method according to the first embodiment, the control unit 150 controls the mounting accommodation device to mount the sapphire substrates 1 on the substrate mounting jig (i.e., the boat 114), which will be described later.

FIG. 2A is a cross sectional view showing a state where substrates to be processed and rings for film forming adjustment are mounted on the substrate mounting jig, and FIG. 2B is a plane view thereof. FIG. 3 is a flowchart illustrating an example of the compound semiconductor film forming method according to the first embodiment of the present disclosure. The cross sectional view of FIG. 2A is obtained by taking along a line 2A-2A in FIG. 2B.

As shown in FIGS. 2A and 2B, in the first embodiment, the sapphire substrates 1 are first mounted in the boat 114 while leaving blanks therebetween. In this embodiment, three blanks are provided. A ring for film forming adjustment 2 is disposed in one of the three blanks. For example, each of the rings for film forming adjustment 2 is mounted on the boat 114 such that a ring portion 2a thereof is positioned above a periphery of a film forming surface of each of the sapphire substrates 1 so as to cover the periphery. The ring for film forming adjustment 2 may be made of any material as long as the compound semiconductor film (e.g., the compound semiconductor film of III-V group) can be formed on the sapphire substrate 1. In such a case, the material of the ring for film forming adjustment 2 may be different from or identical to that of the substrate to be processed. In this embodiment, sapphire identical to the material of the substrate to be processed was used as the material of the ring for film forming adjustment 2.

As described above, the substrates to be processed (the sapphire substrates 1) are mounted on the substrate mounting jig (the boat 114) while leaving the three blanks therebetween and the ring for film forming adjustment 2 is disposed in one of the three blanks. Specifically, the substrates to be processed (the sapphire substrates 1) and the rings for film forming adjustment 2 are alternatively mounted on the substrate mounting jig (the boat 114). Subsequently, the substrate mounting jig (the boat 114) in which the substrates to be processed (the sapphire substrates 1) and the rings for film forming adjustment 2 are accommodated is loaded into the processing chamber 103 (Operation 51 in FIG. 3).

Subsequently, in the inside of the processing chamber 103, the compound semiconductor films are formed on the respective substrates to be processed (the sapphire substrates 1) while the film forming surfaces of the substrates to be processed (the sapphire substrates 1) being oriented to the rear surfaces of the rings for film forming adjustment 2 (Operation S2 in FIG. 3). In this embodiment, the gallium nitride films are formed on the substrates to be processed (the sapphire substrates 1).

As described above, the gallium nitride films are formed on the sapphire substrates 1 using the rings for film forming adjustment 2, which makes it possible to further improve a surface morphology of the gallium nitride film and in-plane uniformity in film thickness thereof as compared with a case where the rings for film forming adjustment 2 are not used.

### <Improvement of Surface Morphology>

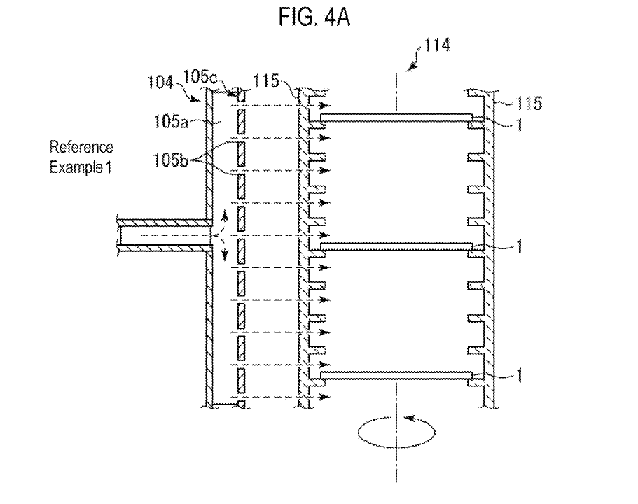

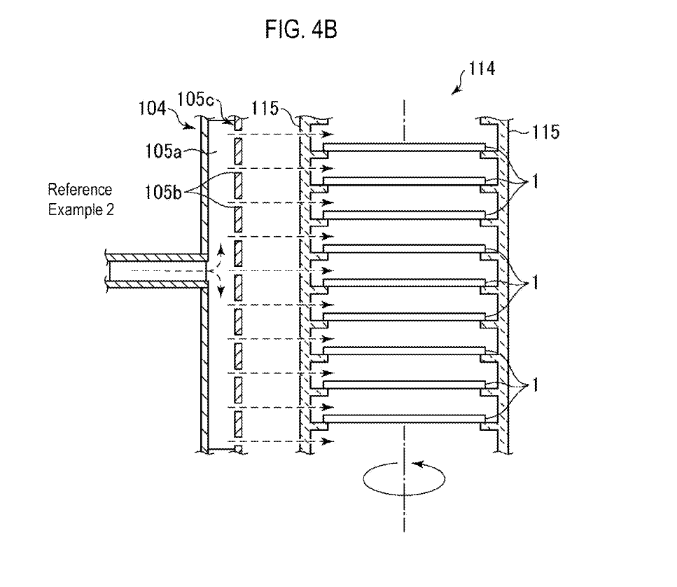

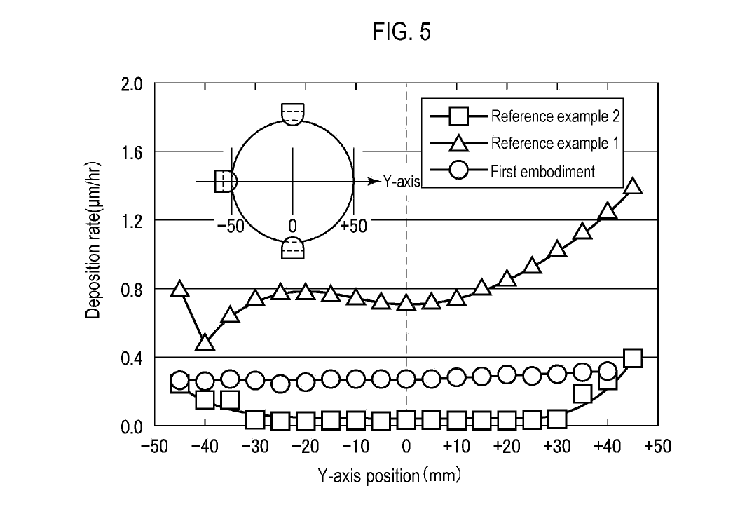

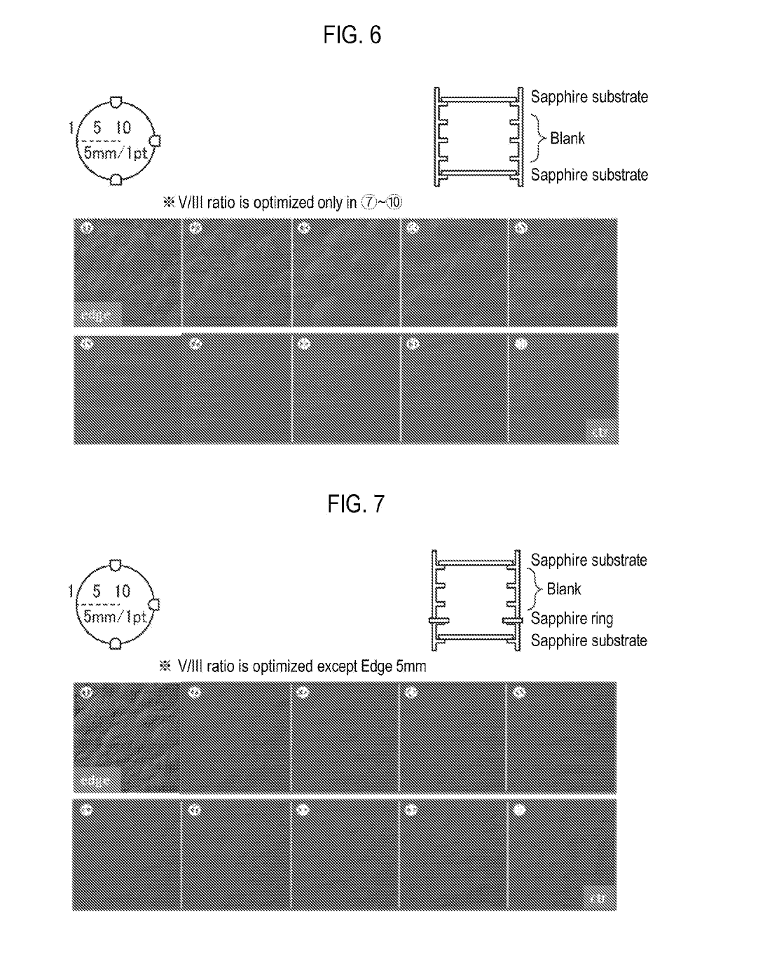

FIGS. 4A and 4B are sectional views showing a state where substrates to be processed are mounted on a substrate mounting jig according to first and second reference examples, respectively. FIG. 5 is a view showing the relationship between a Y-axis position of a substrate to be processed and a deposition rate. FIG. 6 is a photograph showing surface morphologies of formed gallium nitride films.

In the first reference example shown in FIG. 4A, the sapphire substrates 1 are mounted between posts 115 of the boat 114 while leaving, e.g., three blanks therebetween. Subsequently, the gallium trichloride gas and the ammonia gas are supplied into the processing chamber 103 while rotating the boat 114 so that the gallium nitride films are formed on the sapphire substrates 1. Surface morphologies of the formed gallium nitride films are shown in FIG. 6. Observation points are designated by assigning numbers 1 to 10 from the edge of the sapphire substrate 1 toward the center thereof at an interval of 5 mm.

In the first reference example, as shown in FIG. 6, drastic irregularities were manifested on the surfaces of the gallium nitride films at the observation points 1 to 6, which result in an inferior surface morphology. Meanwhile, drastic irregularities were not manifested on the surfaces of the gallium nitride films at the observation points 7 to 10 (the observation point 10: center) when being observed toward the center, which result in a superior surface morphology.

As described above, in the first reference example, the surface morphologies of the gallium nitride films in the range from the edge to the observation point 6 (a position spaced apart 30 mm from the edge), is not better.

As shown in FIG. 5, in the second reference example (see FIG. 4B) in which the sapphire substrates 1 are mounted on the boat 114 without blanks therebetween, the gallium nitride film is formed on the peripheral portion of the sapphire substrate 1 but is substantially not formed on the central portion thereof (as indicated by a symbol “□” in FIG. 5).

The reason for this may be that the film forming surface of the under-lying sapphire substrate 1 faces a rear surface of the upper-lying sapphire substrate 1 during the formation of the gallium nitride film. That is, the gallium nitride film is formed on the rear surface of the upper-lying sapphire substrate 1 in addition to the film forming surface of the upper-lying sapphire substrate 1. This causes the raw material gas of the gallium nitride film to be consumed even in the rear surface of the upper-lying sapphire substrate 1 so that the raw material gas fails to travel up to the central portion of the film forming surface of the sapphire substrate 1 which is to be actually formed.

In consideration of such an assumption, the sapphire substrates 1 are mounted on the boat 114 while leaving the blanks therebetween, which is shown in FIG. 4A as the first reference example.

In the first reference example, the sapphire substrates 1 are mounted on the boat 114 while leaving, e.g., three blanks therebetween, which makes it possible to supply a large amount of the raw material gas of the gallium nitride film between the film forming surface of the under-lying sapphire substrate 1 and the rear surface of the upper-lying sapphire substrate 1 as compared with the second reference example. This makes it possible to form the gallium nitride film on both the peripheral portion and the central portion of the sapphire substrate 1 in the first reference example (as indicated by a symbol “Δ” in FIG. 5).

However, as shown in FIG. 5, a deposition rate in the peripheral portion is drastically faster than that in the central portion. As a result, a thickness of the gallium nitride film to be formed becomes thicker at the peripheral portion and becomes thinner at the central portion, which deteriorates in-plane uniformity in film thickness.

With respect to the first and second reference examples, in the first embodiment in which the film formation is performed in a state where the film forming surface of the sapphire substrate 1 is disposed to face the rear surface of the ring for film forming adjustment 2, the deposition rate is about 0.3 um/hr over the in-plane of the sapphire substrate 1. Therefore, according to the first embodiment, as shown in FIG. 5, the gallium nitride film having a superior in-plane uniformity in film thickness is formed on the sapphire substrate 1 (as indicated by a symbol “∘” in FIG. 5).

The reason for this is that, in the first embodiment, the ring for film forming adjustment 2 is made of quartz, which prevents the gallium nitride film from being formed thereon. In other words, the film forming surface of the sapphire substrate 1 is disposed to face the quartz which prevents the gallium nitride film from being formed thereon. This prevents the raw material gas of the gallium nitride film from being consumed above the film forming surface, which makes it possible to travel the raw material gas of the gallium nitride film up to the central portion of the sapphire substrate 1.

The first reference example showed that the deposition rate is remarkably delayed in the vicinity of the Y-axis position of −40 mm in the sapphire substrate 1. This is probably due to the influence of the quartz posts 115 of the boat 114. As described above, the first reference example showed that the influence caused by the presence or absence of the quartz posts 115 is drastically manifested when the deposition rate is fast, e.g., when exceeding 0.4 um/hr. Specifically, a deterioration in film thickness uniformity which is caused by the presence or absence of the quartz posts 115 can be solved by controlling the deposition rate to, e.g., 0.4 um/hr or lower. This prevents the in-plane uniformity in film thickness of the gallium nitride film to be formed from being influenced by the quartz posts 115.

As described above, according to the first embodiment, the compound semiconductor films (e.g., the compound semiconductor films of the III-V group) are formed on the plurality of sapphire substrates 1, which results in a reduced film forming cost. In this embodiment, the gallium nitride film can be formed with a good production yield and a reduced film forming cost.

Further, during the formation of the gallium nitride film, the film forming surface of the sapphire substrate 1 is disposed to face the ring for film forming adjustment 2 on which the compound semiconductor film to be formed is not formed, which prevents the raw material gas of the compound semiconductor film from being consumed, thus obtaining the compound semiconductor film with a superior in-plane uniformity in film thickness.

Specifically, during the formation of the gallium nitride film, the ring for film forming adjustment 2 covers the periphery of the film forming surface of the sapphire substrate 1 at the upper portion of that periphery. This configuration causes a film forming gas (e.g., gallium trichloride gas) to be consumed at the ring for film forming adjustment 2 prior to reaching the edge of the sapphire substrate 1. Further, this configuration controls the gallium concentration to be kept at an optimal concentration for obtaining the improved surface morphology of the gallium nitride film at the upper portion of the film forming surface of the sapphire substrate 1. It is therefore possible to form the compound semiconductor film having the improved surface morphology, i.e., the gallium nitride film in this embodiment.

FIG. 7 is a photograph showing surface morphologies of the gallium nitride films formed by the compound semiconductor film forming method according to the first embodiment.

As shown in FIG. 7, in the first embodiment, while drastic irregularities are observed on the surface of the gallium nitride film in the vicinity of the observation point 1 (at a position spaced apart from the edge by a distance of 5 mm), drastic irregularities are not observed at the observation points 2 to 10, which results in good surface morphology.

As described above, according to the first embodiment, the ring for film forming adjustment 2 is used in forming the gallium nitride films on the sapphire substrates 1, which makes it possible to form the gallium nitride films with superiority in surface morphology as compared with a case where the ring for film forming adjustment 2 are not used.

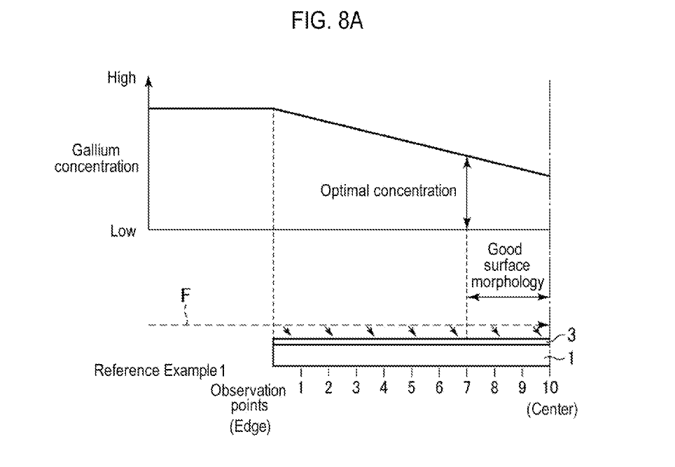

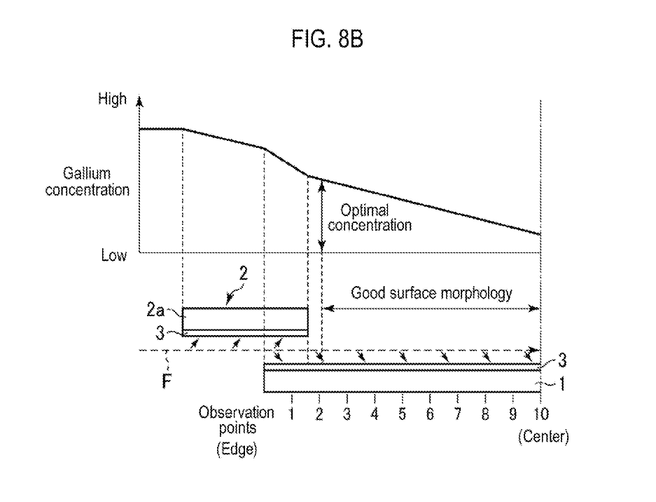

One of the reasons for the surface morphology of the gallium nitride film being improved will be described below. FIGS. 8A and 8B are views showing the relationship between a gallium concentration and a substrate position, FIG. 8A showing the first and second reference examples and FIG. 8B showing the first embodiment.

As shown in FIG. 8A, for the reference example, a gallium-containing gas (e.g., gallium trichloride gas) flows from the edge toward the center of the sapphire substrate 1 being rotated along the film forming surface of the sapphire substrate 1, as indicated by an arrow F. On the film forming surface of the sapphire substrate 1, the gallium trichloride gas flows toward the center of the sapphire substrate 1 while consuming the gallium to form a gallium nitride film 3. As such, a concentration of the gallium is gradually reduced as it goes from the edge of the sapphire substrate 1 toward the center thereof.

The observation points 1 to 7 correspond to the edge of the sapphire substrate 1, which manifest a high gallium concentration. Meanwhile, the observation points 8 to 10 correspond to the central portion of the sapphire substrate 1, which manifest a low gallium concentration compared to the observation points 1 to 7.

As stated above, the surface morphology of the gallium nitride film is closely linked with the gallium concentration, and there exists an optimal gallium concentration for obtaining the good surface morphology of the gallium nitride film. If the gallium concentration on the film forming surface of the sapphire substrate 1 is equal to or smaller than the optimal gallium concentration, drastic irregularities can be removed from the surface of the gallium nitride film, thereby improving the surface morphology of the gallium nitride film.

According to the first embodiment, as indicated by an arrow F in FIG. 8B, a gallium-containing gas (in this embodiment, the gallium trichloride gas) reaches the ring for film forming adjustment 2 prior to arriving at the edge of the sapphire substrate 1. The ring for film forming adjustment 2 is made of, e.g., sapphire. The gallium nitride film 3 is formed on the surface of the ring for film forming adjustment 2. In other words, at a lower side of the ring portion 2a of the ring for film forming adjustment 2, the gallium trichloride gas consumes gallium to form the gallium nitride film 3. For that reason, a concentration of gallium in the gallium trichloride gas is reduced before the gallium trichloride gas reaches the edge of the sapphire substrate 1.

The gallium trichloride gas travels through a space between the ring portion 2a and the film forming surface of the sapphire substrate 1. At this time, since the gallium nitride films 3 are formed on both the ring portion 2a and the sapphire substrate 1, the gallium trichloride gas further consumes gallium.

In addition, when the gallium trichloride gas travels through the ring portion 2a, the gallium trichloride gas consumes gallium to form the gallium nitride film 3 on the sapphire substrate 1.

The first embodiment showed good surface morphology over the observation points 3 to 10. In summary, it was found that the consumption of gallium in the ring for film forming adjustment 2 makes the gallium concentration to be equal to or lower than the optimal gallium concentration over a wider area in the film forming surface of the sapphire substrate 1, thus improving the surface morphology, as compared with the first reference example.

### Second Embodiment

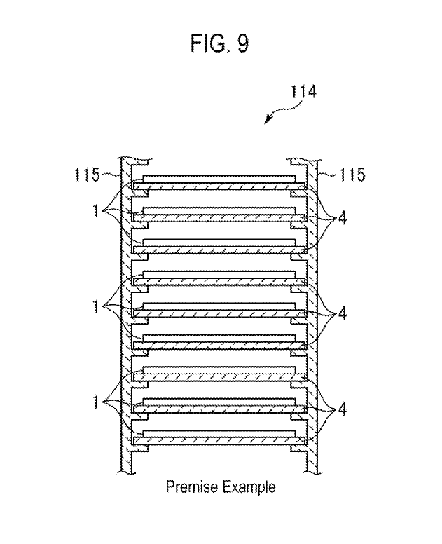

FIG. 9 is a sectional view showing a state where substrates to be processed are mounted on a substrate mounting jig according to a premise example of the second embodiment.

As shown in FIG. 9, in the premise example, the sapphire substrates 1 which are held by respective substrates for film forming adjustment 4 are mounted on the boat 114. Each of the substrates for film forming adjustment 4 is made of a material on which the compound semiconductor film to be formed on the sapphire substrate 1, e.g., the compound semiconductor film of III-V group, is not formed. As an example, if the compound semiconductor film III-V group is the gallium nitride film, the material of the substrate for film forming adjustment 4 may be, e.g., quartz. This is because the gallium nitride film is not formed on the quartz.

As described above, the substrate for film forming adjustment 4 made of the quartz material is disposed opposite to the film forming surface of the sapphire substrate 1, which makes it possible to improve in-plane uniformity in film thickness of the compound semiconductor film of III-V group (e.g., the gallium nitride film) to be formed on the film forming surface of the sapphire substrate 1.

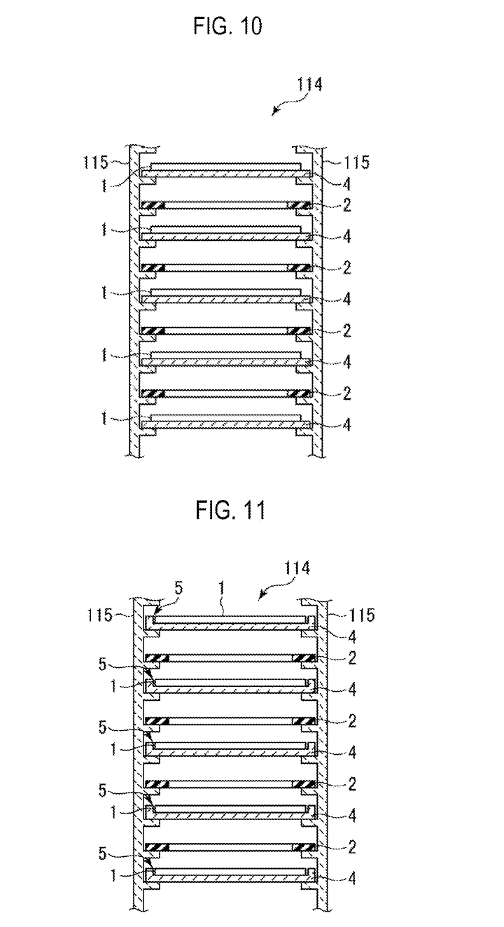

FIG. 10 is a sectional view showing a state where the substrates to be processed 1 are mounted on the substrate mounting jig in a compound semiconductor film forming method according to the second embodiment of the present disclosure.

As shown in FIG. 10, the second embodiment is similar to the first embodiment excepted that the combination of the ring for film forming adjustment 2 and the substrate for film forming adjustment 4 is used in forming the compound semiconductor films. In this embodiment, each of the sapphire substrates 1 is directly mounted on a respective substrate for film forming adjustment 4 and is mounted on the boat 114 while leaving one blank therebetween. Each of the rings for film forming adjustment 2 is mounted in the one blank.

As described above, both the rings for film forming adjustment 2 and the substrates for film forming adjustment 4 are used in forming the compound semiconductor films (e.g., the compound semiconductor films of III-V group), which makes it possible to obtain the compound semiconductor films of III-V group (in this embodiment, the gallium nitride films) having good surface morphology, similarly to the first embodiment. In addition, the use of the substrates for film forming adjustment 4 further improves in-plane uniformity in film thickness of the gallium nitride film.

### FIRST MODIFIED EXAMPLE

FIG. 11 is a sectional view showing a state where substrates to be processed and substrates for film forming adjustment are mounted on a substrate mounting jig according to a first modified example of the second embodiment.

As shown in FIG. 11, each of the substrates for film forming adjustment 4 includes a recess 5 for accommodating the sapphire substrate 1 therein.

The recess 5 blocks a lateral side portion of the sapphire substrate 1 with an inner lateral side of the recess 5, which makes it possible to prevent, e.g., the raw material gas of the gallium nitride film from being wastefully consumed at the lateral side portion of the sapphire substrate 1. This prevention further improves in-plane uniformity in film thickness of the compound semiconductor film of III-V group, e.g., the gallium nitride film.

### SECOND MODIFIED EXAMPLE

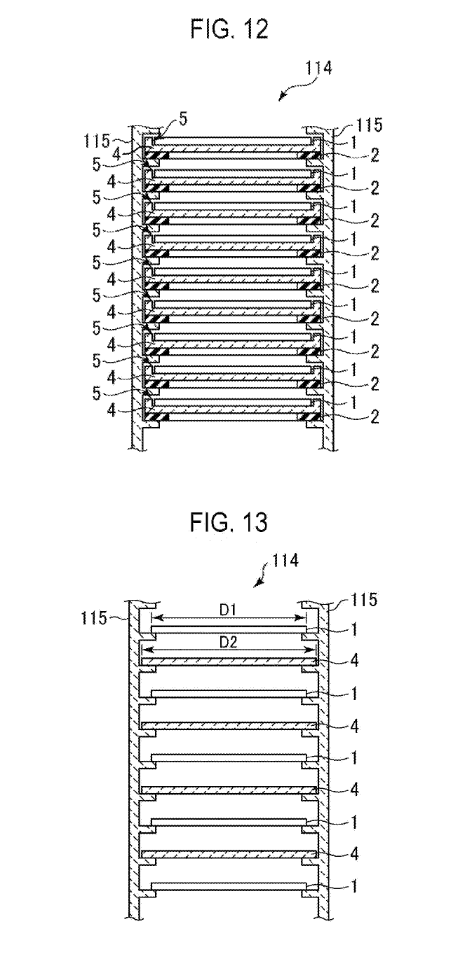

FIG. 12 is a sectional view showing a state where substrates to be processed and substrates for film forming adjustment are mounted on a substrate mounting jig according to a second modified example of the second embodiment.

As shown in FIG. 12, each of the sapphire substrates 1, which is directly mounted on the substrate for film forming adjustment 4, may be mounted on the boat 114 without having to leave any blanks therebetween.

In this case, the substrate for film forming adjustment 4 with the sapphire substrate 1 mounted therein is first mounted on the ring for film forming adjustment 2, and then the ring for film forming adjustment 2 and the substrate for film forming adjustment 4 which are disposed in this manner, are mounted on the boat 114.

According to the second modified example configured as above, it is possible to mount the sapphire substrates 1 on the boat 114 with no blank, thus further increasing the number of the sapphire substrates 1 that can be processed at one time, as compared with mounting the sapphire substrates 1 while leaving blanks therebetween,

### THIRD MODIFIED EXAMPLE

FIG. 13 is a sectional view showing a state where substrates to be processed and substrates for film forming adjustment are mounted on a substrate mounting jig according to a third modified example of the second embodiment.

As shown in FIG. 13, the size (e.g., diameter D2) of the substrate for film forming adjustment 4 is larger than a diameter D1 of the sapphire substrate 1. With this configuration, the substrate for film forming adjustment 4 can cover the rear surface of the sapphire substrate 1 disposed thereabove.

This prevents the raw material gas of the compound semiconductor film (e.g., compound semiconductor film of III-V group) from being unnecessarily consumed above the film forming surface of the sapphire substrate 1, which makes it possible to further improve in-plane uniformity in film thickness of the compound semiconductor film of III-V group, e.g., the gallium nitride film.

### FOURTH MODIFIED EXAMPLE

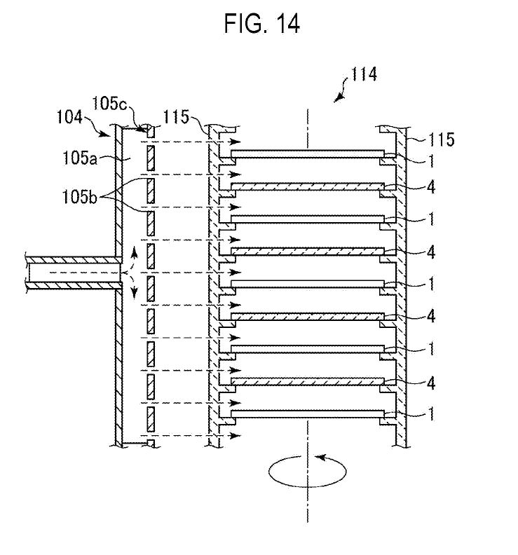

FIG. 14 is a sectional view showing a state where substrates to be processed and substrates for film forming adjustment are mounted on a substrate mounting jig according to a fourth modified example of the second embodiment.

As shown in FIG. 14, in the fourth modified example, the sapphire substrates 1 and the substrates for film forming adjustment 4 are alternately mounted on the boat 114. By doing this, each of the sapphire substrates 1 is mounted on the boat 114 in a state where the film forming surface of the sapphire substrate 1 faces the rear surface of the substrate for film forming adjustment 4. Example of a material of the substrate for film forming adjustment 4 may include one which prevents the compound semiconductor film (e.g., compound semiconductor film of III-V group) to be formed on the sapphire substrate 1 from being formed thereon. When the compound semiconductor film of III-V group is the gallium nitride film, for example, quartz may be selected as the material of the substrate for film forming adjustment 4. In this example, the compound semiconductor film of III-V group to be formed is the gallium nitride film. Because of this, the quartz was selected as the material of the substrate for film forming adjustment 4.

As described above, the substrates to be processed (the sapphire substrates 1) and substrates for film forming adjustment 4 (i.e., quartz substrates) are alternately mounted on the substrate mounting jig (i.e., the boat 114), and the substrate mounting jig (i.e., the boat 114) accommodating the sapphire substrates 1 and the substrates for film forming adjustment 4 therein is loaded in the processing chamber 103.

In the first embodiment, the sapphire substrates 1 and the rings for film forming adjustment 2 are alternately mounted on the boat 114.

In such a mounting, the rings for film forming adjustment 2 are alternately disposed in grooves formed in each of the posts 115 at intervals of one groove. This allows the sapphire substrates 1 to be mounted on the boat 114 by a half of the number of the grooves, which decreases the number of the sapphire substrates 1 usable in the film forming process at a time.

### Third Embodiment

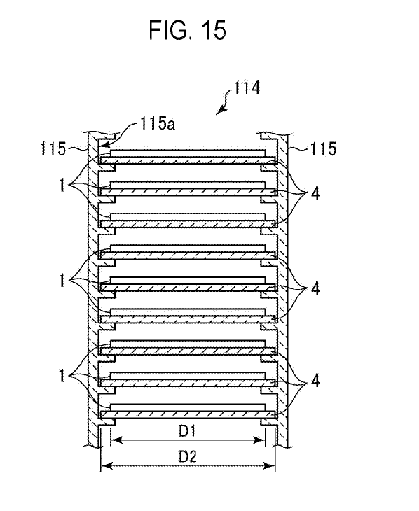

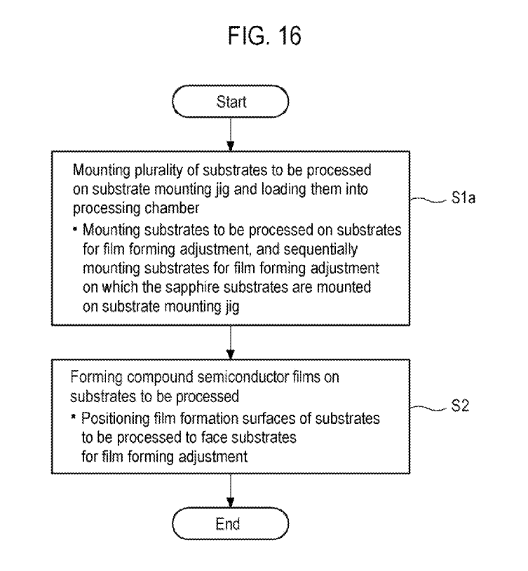

FIG. 15 is a sectional view showing a state where substrates to be processed and substrates for film forming adjustment are mounted on a substrate mounting jig using a compound semiconductor film forming method according to a third embodiment of the present disclosure. FIG. 16 is a flowchart illustrating an example of the compound semiconductor film forming method according to the third embodiment of the present disclosure.

As shown in FIG. 15, in the compound semiconductor film forming method according to the third embodiment, the sapphire substrates 1 are directly mounted on the substrates for film forming adjustment 4, respectively. Each of the substrates for film forming adjustment 4 on which the sapphire substrate 1 is formed, is mounted on the boat 114. In the third embodiment, each of the substrates for film forming adjustment 4 with the sapphire substrate 1 formed thereon is mounted on a respective one of supporting grooves 115a formed in each of the posts 115 of the boat 114.

As described above, the sapphire substrates 1 are directly on the substrates for film forming adjustment 4 so that they can be mounted on the respective supporting grooves 115a.

Therefore, the third embodiment may be as effective as the first embodiment as described above and is capable of further increasing the number of the sapphire substrates 1 usable in the film forming process at a time.

As shown in Operation S1a of FIG. 16, each of a plurality of sapphire substrates to be processed (i.e., the sapphire substrates 1) is mounted on each of the substrates for film forming adjustment 4. Subsequently, the substrates for film forming adjustment 4 on each of which the sapphire substrate 1 is mounted are sequentially mounted on the substrate mounting jig (i.e., the boat 114).

Thereafter, as shown in Operation S2 of FIG. 16, similar to the first embodiment, the compound semiconductor films (e.g., the gallium nitride films) are formed on the plurality of substrates to be processed (i.e., the sapphire substrates 1), respectively, in a state where the film forming surface of each of the sapphire substrates 1 faces the rear surface of each of the substrates for film forming adjustment 4.

Further, in the third embodiment, as shown in FIG. 13, the substrate for film forming adjustment 4 having the diameter D2 larger than the diameter D1 of the sapphire substrate 1 may be preferably used. The reason for this is that each of the substrates for film forming adjustment 4 is mounted on the boat 114 while sufficiently covering the rear surface of each of the sapphire substrates 1.

### MODIFIED EXAMPLE

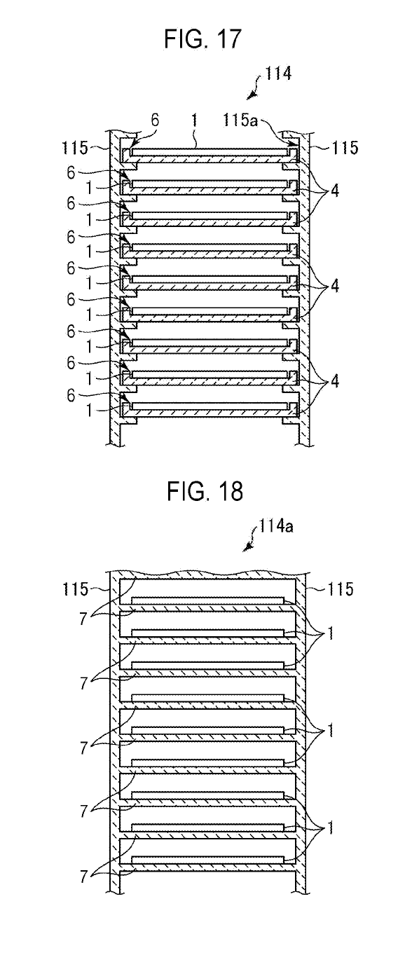

FIG. 17 is a sectional view showing a state where substrates to be processed and substrates for film forming adjustment are mounted on a substrate mounting jig according to a modified example of the third embodiment of the present disclosure.

As shown in FIG. 17, the substrate for film forming adjustment 4 includes a recess 6 configured to receive the sapphire substrate 1 therein such that the sapphire substrate 1 is directly mounted on the substrate for film forming adjustment 4.

This configuration makes it possible to cover an outer lateral side of the sapphire substrate 1 with an inner lateral side of the recess 6, thus preventing the raw material gas of the gallium nitride film from being unnecessarily consumed at the outer lateral side of the sapphire substrate 1. This further improves in-plane uniformity in film thickness of the compound semiconductor film, e.g., the gallium nitride film.

### Fourth Embodiment

FIG. 18 is a sectional view showing a state where substrates to be processed are mounted on a substrate mounting jig using a compound semiconductor film forming method according to a fourth embodiment of the present disclosure.

As shown in FIG. 18, the fourth embodiment is different from the first to third embodiments in a structure of the boat 114. A boat 114a according to the fourth embodiment includes a plurality of mounting portions 7 configured to receive each of the sapphire substrate 1 therein. In this configuration, each of rear surfaces of the mounting portions 7 opposite to each of the film forming surfaces of the sapphire substrates 1 is made of a material which prevents the compound semiconductor film to be formed on the sapphire substrate 1 from being formed thereon.

As described above, in the fourth embodiment, the film forming surface of the sapphire substrate 1 is disposed to face the material which prevents the compound semiconductor film to be formed on the sapphire substrate 1 from being formed thereon. Thus, during the formation of the compound semiconductor film, the use of the boat 114a including the mounting portions 7 configured as above is as effective as the first to third embodiments.

In the case that the gallium nitride films is formed on the sapphire substrate 1, examples of the material which prevents the compound semiconductor film to be formed on the sapphire substrate 1 from being formed thereon may include quartz. For example, the mounting portions 7 may be formed of quartz.

### MODIFIED EXAMPLE

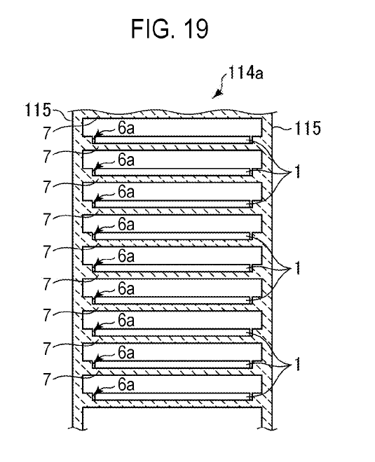

FIG. 19 is a sectional view showing a state where substrates to be processed are mounted on a substrate mounting jig according to a modified example of the fourth embodiment of the present disclosure.

As shown in FIG. 19, the mounting portion 7 may include a recess 6a having the same configuration as the recess 6 shown in FIG. 17.

The sapphire substrate 1 is received in the recess 6a of the mounting portions 7 so that the outer lateral side of the sapphire substrate 1 is covered with an inner lateral side of the recess 6a. This prevents the raw material gas of the gallium nitride film from being consumed at the outer lateral side of the sapphire substrate 1, which makes it possible to further improve in-plane uniformity in film thickness of the compound semiconductor film, e.g., the gallium nitride film.

### Fifth Embodiment

A fifth embodiment is directed to a batch-type vertical film forming apparatus, which can be preferably used in performing the compound semiconductor film forming method according to the above embodiments of the present disclosure.

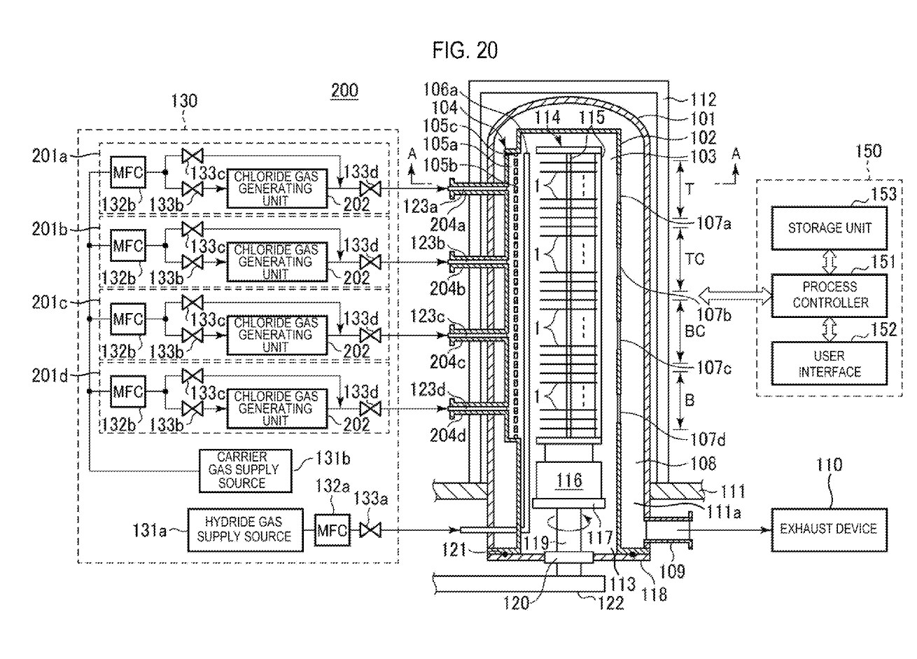

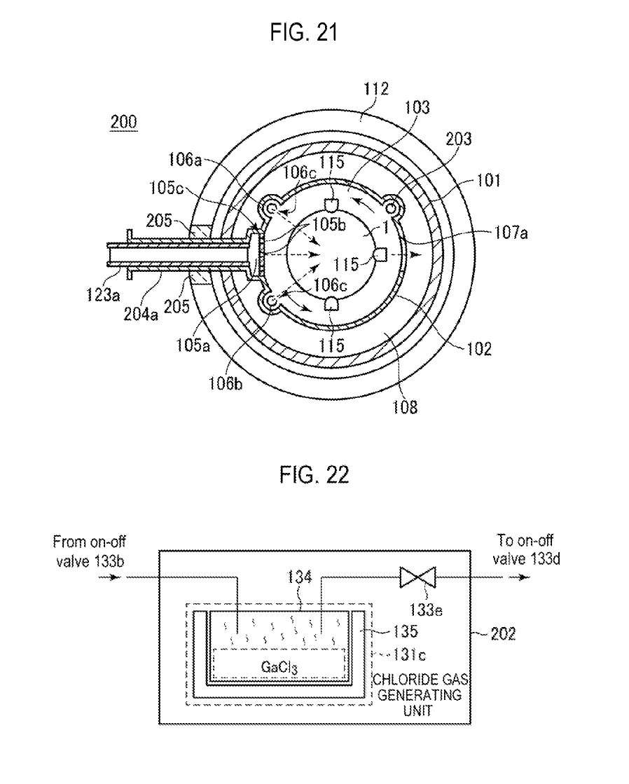

FIG. 20 is a longitudinal sectional view schematically showing an example of a batch-type vertical film forming apparatus according to the fifth embodiment of the present disclosure. FIG. 21 is a schematic traverse sectional view of the batch-type vertical film forming apparatus taken along a line A-A in FIG. 20.

A batch-type vertical film forming apparatus (hereinafter, referred to as a “film forming apparatus”) 200 shown in FIG. 20 is different from the film forming apparatus 100 shown in FIG. 1 in that gas supply systems configured to supply a chloride gas containing one element of a compound semiconductor film to be formed are independently disposed corresponding to each zone. In the fifth embodiment, four zones, i.e., a bottom zone B, a bottom-center zone BC, a top-center zone TC and a top zone T, are arranged in that order from the bottom of the inner tube 102. If it is assumed that the boat 114 can load, e.g., 100 sheets of the sapphire substrates 1, each of the four zones B, BC, TC and T corresponds to 25 sheets of the sapphire substrates 1. Gas supply systems 201a to 201d are connected to the four zones B, BC, TC and T, respectively. Similar to the configuration of the film forming apparatus 100 shown in FIG. 1, each of the gas supply systems 201a to 201d is provided with the mass flow controller (MFC) 132b, the on-off valve 133b, the bypass on-off valve 133c and the on-off valve 133d. Each of the gas supply systems 201a to 201d is further provided with a chloride gas generating unit 202. The chloride gas contains the one element of the compound semiconductor film to be formed. In this embodiment, the chloride gas is a gallium trichloride gas containing gallium.

FIG. 22 is a block diagram showing a configuration of the chloride gas generating unit 202.

As shown in FIG. 22, each of the chloride gas generating units 202 include the chloride source 131c and the on-off valve 133e, similar to the film forming apparatus 100 shown in FIG. 1. The film forming apparatus 200 of this fifth embodiment includes the four chloride gas generating units 202, and the number of the chloride source 131c and the on-off valves 133e is four.

Each of the chloride gas generating units 202 handles, e.g., about 25 sheets of the sapphire substrates 1, out of 100 sheets of the sapphire substrates 1. The chloride gas is supplied from each of the chloride gas generating units 202 to the bottom zone B, the bottom-center zone BC, the top-center zone TC and the top zone T. In this embodiment, with respect to about 25 sheets of the sapphire substrates 1, the gallium trichloride gas is supplied horizontally toward the bottom zone B, the bottom-center zone BC, the top-center zone TC and the top zone T in a side flow manner.

In the film forming apparatus 200, a hydride gas is supplied in the same manner as in the film forming apparatus 100 shown in FIG. 1. The hydride gas contains another element different from the one element of the compound semiconductor film to be formed. In this embodiment, the hydride gas is a nitrogen-containing ammonia.

As shown in the traverse sectional view of FIG. 21, the film forming apparatus 200 includes two gas introduction pipes 106a and 106b. The hydride gas is commonly supplied from the gas introduction pipes 106a and 106b vertically extending from the lower portion of the inner tube 102, to the four zones through a plurality of gas discharge holes 106c formed in the gas introduction pipes 106a and 106b. In this embodiment, an ammonia gas is horizontally discharged from the gas discharge holes 106c and is supplied to substantially central portions of 100 sheets of the sapphire substrates 1.

As shown in the traverse sectional view of FIG. 21, in addition to the gas introduction pipes 106a and 106b, a temperature controller 203 vertically extending from the lower portion of the inner tube 102 is disposed inside the processing chamber 103. The temperature controller 203 monitors an internal temperature of the processing chamber 103 and feeds back the monitored results to the process controller 151. Based on the fed-back monitored results, the process controller 151 controls the heating device 112 so that the internal temperature of the processing chamber 103 is kept at, e.g., a predetermined temperature.

Each of horizontally-extended guide pipes 204a to 204d (see reference symbol 204a in FIG. 21) may be installed along the periphery of each of the gas introduction pipes 123a to 123d (see reference symbol 123a in FIG. 21) to support each of the gas introduction pipes 123a to 123d.

In some embodiments, heat insulating members 205 may be installed between each of the guide pipes 204a to 204d and the heating device 112. The heat insulating members 205 make, e.g., the gallium trichloride gas flowing through the gas introduction pipes 123a to 123d less likely to be affected by the heat of the heating device 112. This facilitates the supply of the gallium trichloride gas into the processing chamber 103 at a designed activity.

In the film forming apparatus 200 according to the fifth embodiment, a traveling distance of gas from each gas generating unit (e.g., each of the chloride gas generating units 202) up to the processing chamber 103 is reduced by horizontally arranging the gas introduction pipes 123a to 123d. The gas has a low pyrolysis temperature and a relatively large consumption property within the processing chamber 103 and is, e.g., the gallium trichloride gas. The shortening of the traveling distance prevents the activity of the gallium trichloride gas from being decreased within, e.g., the gas introduction pipes 123a to 123d, the gas introduction portion 104 and the processing chamber 103. With this configuration, it is possible to supply the gallium trichloride gas into the processing chamber 103 at a high activity, which enables the gallium trichloride gas to make contribution to the formation of the compound semiconductor film in an efficient manner.

As described above, the gas supply systems 201a to 201d are independently disposed corresponding to each of the zones without having to use a single gas supply system with respect to all the sapphire substrates 1 accommodated in the processing chamber 103. This configuration further prevents the activity of the gallium trichloride gas from being reduced within the vertically-elongated gas introduction portion 104 and the vertically-elongated processing chamber 103.

The gas introduction pipes 123a to 123d are disposed to extend in the horizontal direction and not in the vertical direction. With this configuration, it is possible to supply the chloride gas from each of the chloride gas generating units 202 horizontally extended to the processing chamber 103 at a shortest distance. Further, regions of the gas introduction pipes 123a to 123d facing the heating device 112 vertically extended are reduced, which makes it possible to make the gas (e.g., the gallium trichloride gas) flowing through each of the gas introduction pipes 123a to 123d less likely to be affected by the heating device 112.

On the contrary, a traveling distance of a gas (e.g., the ammonia gas) requiring high activation energy is set to be longer than that of the gallium trichloride gas. In this embodiment, the ammonia gas is configured to travel through the gas introduction pipes 106a and 106b vertically extending from the lower portion of the inner tube 102 inside the vertically-elongated processing chamber 103. The lengthening of the traveling distance of the ammonia gas allows an increased amount of heat energy to be applied to the ammonia gas, which further increases the activity. With this configuration, it is possible to supply the ammonia gas into the processing chamber 103 at a high activity, which enables the ammonia gas to make contribution to the formation of the compound semiconductor film in an efficient manner.

As described above, in the film forming apparatus according to the fifth embodiment, the traveling distances of the gas containing one element that constitutes the compound semiconductor and the gas containing another element that constitutes the compound semiconductor and different from the one element are set as appropriate. With this configuration, the gas containing the one element and the gas containing the other element can be supplied into the processing chamber 103 at a high activity. This makes it possible to efficiently form the compound semiconductor film.

An example of formation conditions of the compound semiconductor film (e.g., the gallium nitride film) formed by the film forming apparatus 200 is as follows:

Film forming temperature: 1,000 degrees C.

Film forming pressure: 133 Pa (1 Torr)

N₂ gas flow rate: 50 sccm (for picking up GaCl₃ gas)

NH₃ gas flow rate: 2 slm

Since the film forming time is changed depending on the thickness of the gallium nitride film, it is not indicated herein. The film forming time may be appropriately adjusted depending on the thickness of the gallium nitride film.

In some embodiments, during the formation of the gallium nitride film, the GaCl₃ gas and the NH₃ gas may be simultaneously supplied into the processing chamber 103. Alternatively, the GaCl₃ gas and the NH₃ gas may be alternately supplied into the processing chamber 103.

While in above embodiment, the two gas introduction pipes 106a and 106b has been described to be disposed in the film forming apparatus 200, at least one gas introduction pipe may be installed in the vicinity of the sapphire substrates 1 in view of a given gas flow rate and a gas supply uniformity.

While the first to fifth embodiments of the present disclosure have been described above, the present disclosure is not limited to the first to fifth embodiments but may be modified in many different forms without departing from the spirit and scope of the present disclosure.

As an example, in the first and second embodiments, the ring portion 2a of the ring for film forming adjustment 2 has been described to be arranged above the periphery of the film forming surface of the sapphire substrate 1 to cover the periphery of the sapphire substrate 1. Alternatively, as long as the one element (e.g., a gallium as a chemical element of III group) that constitutes the compound semiconductor can reach above the film forming surface of the sapphire substrate 1 at an optimal concentration required to improve the surface morphology of the compound semiconductor film of III-V group to be formed, the ring portion 2a may be configured not to cover above the periphery of the film forming surface of the sapphire substrate 1 but to cover only above the outer peripheral portion of the sapphire substrate 1.

Further, while in the first and second embodiments, the ring for film forming adjustment 2 has been described to be made of sapphire, only the surface of the ring for film forming adjustment 2 may be coated with the sapphire, instead of coating the entire ring for film forming adjustment 2 with the sapphire.

While in the first and second embodiments, the ring for film forming adjustment 2 has been described to be made of quartz, only the surface of the ring for film forming adjustment 2 may be coated with quartz, instead of making the entire of the ring for film forming adjustment 2 of quartz. Alternatively, a surface of the ring for film forming adjustment 2 facing the film forming surface of the sapphire substrate 1 may be coated with quartz.

While in the second embodiment, the substrate for film forming adjustment 4 used in combination with the ring for film forming adjustment 2 has been described to be made of quartz, only the surface of the substrate for film forming adjustment 4 may be coated with quartz, instead of making the entire substrate for film forming adjustment 4 of quartz. Alternatively, a surface of the substrate for film forming adjustment 4 facing the film forming surface of the sapphire substrate 1 may be coated with quartz.

Further, in some embodiments, in addition to the substrate for film forming adjustment 4, a front surface of the mounting portion 7 illustrated in the fourth embodiment may be coated with quartz. Alternatively, the front surface of the mounting portion 7 may be coated with an oxide or a metal oxide which prevents the compound semiconductor film to be formed from being formed thereon. In some embodiments, the rear surface of the mounting portion 7 facing the film forming surface of the sapphire substrate 1 may be coated with quartz. Alternatively, the rear surface of the mounting portion 7 may be coated with the oxide of the metal oxide.

While in the above embodiments, the sapphire substrate has been described to be used as the substrate on which the compound semiconductor film is to be formed, the present disclosure is not limited thereto. As an example, a SiC substrate or a Si substrate may be used as the substrate.

In some embodiments, the surface of the substrate for film forming adjustment 4 may be coated with a metal oxide instead of quartz. Alternatively, the surface of the substrate for film forming adjustment 4 facing the film forming surface of the sapphire substrate 1 may be coated with an oxide (e.g., metal oxide) instead of quartz. In this case, an oxide or a metal oxide which prevents a compound semiconductor film from being formed thereon may be selected.

While in the above embodiments, the gallium nitride film has been described to be formed using the batch-type vertical film forming apparatus, a single-type film forming apparatus or another batch-type film forming apparatus may be employed instead of the batch-type vertical film forming apparatus.

In the above embodiments, a method of vaporizing the solid gallium trichloride, picking up a generated gallium trichloride gas and transferring the same the processing chamber 103 together with a carrier gas is described as the method of forming the compound semiconductor film, e.g., the gallium nitride film. This film forming method is often called a chloride transport CVD (LP-CVD) method. However, the method of forming the compound semiconductor film is not limited to the aforementioned embodiments but may be a HVPE method or a MOCVD method.

While in the above embodiments, the chloride gas containing the one element that constitutes the compound semiconductor has been described to be supplied into the processing chamber 103 in order to form the compound semiconductor film, a halogen gas may be supplied depending on the kind of the compound semiconductor film to be formed, instead of the chloride gas.

While in the above embodiments, the nitride semiconductor film, e.g., the gallium nitride film, has been described to be used as one example of the compound semiconductor film, the present disclosure may be applied even when forming a nitride semiconductor film, a compound semiconductor film of III-V group or a compound semiconductor film of II-IV group, other than the gallium nitride film. In these cases, a material on which the compound semiconductor film of III-V group or the compound semiconductor film of II-IV group is formed thereon, e.g., a material identical to that of a substrate on which the compound semiconductor film is to be formed, may be selected as the material or the coating material of the ring for film forming adjustment 2. This configuration results in the same effects as that in the first and the second embodiments.

While in the above embodiments, the nitride semiconductor film (e.g., the gallium nitride film) has been described to be used as one example of the compound semiconductor film, the present disclosure may be applied even when forming a nitride semiconductor film, a compound semiconductor film of III-V group or a compound semiconductor film of II-IV group, other than the gallium nitride film. In these cases, a material which prevents the compound semiconductor film of III-V group to be formed or the compound semiconductor film of II-IV group to be formed from being substantially formed thereon, for example, the quartz, the oxide or the metal oxide, may be selected as the material or the coating material of the ring for film forming adjustment 2 or the mounting portion 7. This configuration results in the same effects as that in the first to fourth embodiments.

In the above embodiments, the material (e.g., the quartz, the oxide or the metal oxide), which prevents the compound semiconductor film of III-V group to be formed or the compound semiconductor film of II-IV group to be formed from being substantially formed thereon, has been described to be selected as the material or the coating film of the substrate for film forming adjustment 4 of the second embodiment. This configuration results in the same effects as that in the second embodiment.

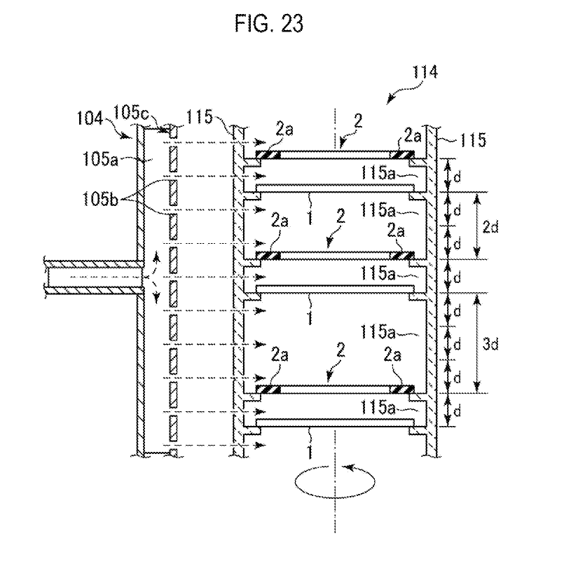

In the above embodiments, the grooves are formed in the posts 115 of the boat 114 at a regular interval of d and the sapphire substrates 1 are mounted in the grooves. For example, in the first embodiment, one sapphire substrate 1 is mounted in one of four grooves formed at the regular interval of d, and the ring for film forming adjustment 2 is mounted in one of three blanks. Thus, the interval between the ring for film forming adjustment 2 and the sapphire substrate 1 is equal to “3d”. However, the grooves may not be formed at the regular interval of d. Alternatively, the interval between the ring for film forming adjustment 2 and the sapphire substrate 1 may be set to be “2d” or greater, as shown a modified example in FIG. 23.

As shown in FIG. 23, grooves 115a are formed in the post 115 at intervals of “d”, “2d” and “3d”. The boat 114 may be modified in this manner. Further, as shown in FIG. 23, in addition to the grooves 115a having an interval of “d”, the grooves 115a having intervals of “2d” and “3d” may be formed together. Alternatively, both the grooves 115a having intervals of “d” and “2d” may be formed. As a further alternative example, both the grooves 115a having intervals of “d” and “3d” may be formed. The interval are preferably equal to or larger than “d”. Practically, it is preferred that the interval is “2d” or greater.

In the above embodiments, a material (e.g., the quartz, the oxide or the metal oxide) on which the compound semiconductor film of III-V group or the compound semiconductor film of II-IV group is not formed or substantially not formed, has been described to be selected as the materials or the coating films of components (e.g., the outer tube 101 and the inner tube 102) that constitutes the processing chamber 103 and components (e.g., the gas introduction portion 104, the gas introduction pipe 106, the boat 114 and the posts 115) accommodated in the processing chamber 103. This configuration results in the same effects as that in the first to third embodiments.

According to the present disclosure, it is possible to provide a compound semiconductor film forming method and apparatus thereof, which are capable of improving a production yield, reducing film forming costs, enhancing in-plane uniformity in film thickness of the compound semiconductor film to be formed and achieving an improved surface morphology.

While certain embodiments have been described, these embodiments have been presented by way of example only, and are not intended to limit the scope of the disclosures. Indeed, the novel methods and apparatuses described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

1. A method for forming a compound semiconductor film on a substrate to be processed, comprising:
mounting a plurality of substrates to be processed on a substrate mounting jig;
loading the substrates to be processed into a processing chamber; and
heating the substrates to be processed loaded into the processing chamber;
supplying a gas containing one element that constitutes a compound semiconductor, and another gas containing another element that constitutes the compound semiconductor and being different from the one element, into the processing chamber in which the substrates to be processed are loaded; and
forming the compound semiconductor film on each of the substrates to be processed,
wherein the loading includes:
mounting the substrates to be processed on the substrate mounting jig while leaving at least one blank therebetween;
placing a ring for film forming adjustment which is used in forming the compound semiconductor film on the substrate to be processed in the at least one bank; and
loading the substrates to be processed and the rings for film forming adjustment into the processing chamber, and
wherein the forming includes forming the compound semiconductor films on the substrates to be processed while a film forming surface of each of the substrates to be processed being disposed to face each of the rings for film forming adjustment.

2. The method of claim 1, wherein the substrate mounting jig is configured to mount the substrates to be processed and the rings for film forming adjustment thereon along a vertical direction.

3. The method of claim 1, wherein the rings for film forming adjustment are larger in size than the substrates to be processed, and
wherein each of the rings for film forming adjustment includes a ring portion facing at least a periphery of each of the substrates to be processed.

4. The method of claim 1, wherein the forming includes rotating the substrate mounting jig on which the substrates to be processed and the rings for film forming adjustment are mounted.

5. The method of claim 4, wherein the supplying includes supplying the gas containing the one element and the another gas containing the another element along the film forming surface of each of the substrates to be processed.

6. The method of claim 1, wherein a material of each of the rings for film forming adjustment is identical to that of each of the substrates to be processed.

7. The method of claim 1, wherein the compound semiconductor film is a nitride semiconductor film using nitrogen as a chemical element of V group.

8. The method of claim 7, wherein the nitride semiconductor film is a gallium nitride film.

9. The method of claim 1, wherein the mounting includes:
placing the substrates to be processed on substrates for film forming adjustment on each of which the compound semiconductor film to be formed on the substrate to be processed is not formed;
mounting the substrates for film forming adjustment on which the substrates to be processed are placed on the substrate mounting jig.

10. The method of claim 9, wherein each of the substrates for film forming adjustment includes a recess configured to accommodate each of the substrates to be processed therein.

11. The method of claim 9, wherein, when the compound semiconductor film is a gallium nitride film, the substrates for film forming adjustment are made of quartz or the surfaces of the substrates for film forming adjustment facing the film forming surfaces of the substrates to be processed are covered with quartz.

12. The method of claim 9, wherein the mounting includes alternately mounting the substrates to be processed and the substrates for film forming adjustment on which the compound semiconductor films to be formed on the substrates to be processed are not formed, on the substrate mounting jig.

13. An apparatus of forming a compound semiconductor film on a substrate to be processed, comprising:
a processing chamber configured to accommodate a substrate mounting jig on which a plurality of substrates to be processed are mounted, the compound semiconductor film being formed on each of the plurality of substrates to be processed;
a gas supply unit configured to supply a gas containing one element that constitutes a compound semiconductor and another gas containing another element that constitutes the compound semiconductor and being different from the one element into the processing chamber accommodating the substrates to be processed therein;
a heating unit configured to heat the substrates to be processed accommodated in the processing chamber;
a mounting and loading unit configured to mount the substrates to be processed on the substrate mounting jig and configured to load the substrates to be processed mounted on the substrate mounting jig into the processing chamber; and
a control unit configured to control the gas supply unit, the heating unit and the mounting and loading unit,
wherein the control unit is configured to control the gas supply unit, the heating unit and the mounting and loading unit to perform the method of claim 1.

14. The apparatus of claim 13, wherein the compound semiconductor film is a nitride semiconductor film using nitrogen as a chemical element of V group.

15. The apparatus of claim 14, wherein the nitride semiconductor film is a gallium nitride film.

16. The apparatus of claim 13, wherein, when the compound semiconductor film is a gallium nitride film, substrates for film forming adjustment on each of which the compound semiconductor film to be formed on the substrate to be processed is not formed are made of quartz or surfaces of the substrates for film forming adjustment facing at least the film forming surfaces of the substrates to be processed are covered with quartz.

17. The apparatus of claim 13, wherein the substrate mounting jig includes a plurality of mounting portions on which the substrates to be processed are mounted,
wherein a surface of each of the mounting portions facing a film forming surface of each of the substrates to be processed is made of a material which prevents the compound semiconductor films to be formed on the substrates to be processed from being formed thereon.

18. The apparatus of claim 17, wherein each of the mounting portions includes a recess configured to receive each of the substrates to be processed therein.
